(19) United States
(12) Patent Application Publication
(10) Pub. No.: US 2015/0076963 A1
(43) Pub. Date: Mar. 19, 2015

(54) Generator of electricity and refrigeration using induced vibrational and acoustic potential energy reclamation via tuned piezoelectric resonant cavity systems

(71) Applicant: Timothy James Sipp, Albuquerque, NM (US)

(72) Inventor: Timothy James Sipp, Albuquerque, NM (US)

(21) Appl. No.: 13/919,896

(22) Filed: Sep. 16, 2013

(51) Int. Cl. H01L 41/107; H01L 41/09; H01L 41/113; H01L 41/04

(52) U.S. Cl. CPC H01L 41/107; H01L 41/042; H01L 41/09; H01L 41/113
USPC 310/316.01

(57) ABSTRACT

A plurality of pressurized sequentially perpendicularly coupled and tuned piezoelectric resonators mechanically amplifies ambient and induced Sound Pressure Levels via Standing Wave Resonance such that the anti-node of the Natural Resonant Frequency in each resonator occurs in a plane consistent with the coupling port of the subsequent resonator thereby acting as a mechanically amplified acoustic driver for the proceeding resonator until acoustically driving mechanically coupled and tuned Piezoelectric Helmholtz resonators with physical parameters such that Standing Wave Resonance occurs within the Piezoelectric Helmholtz Resonant Cavities and Acoustic Refrigeration Units comprising cylindrical resonant cavities with axial regenerating stacks acted upon by tuned frequencies such that the hot heat exchangers are in the center of said cavities while the cold heat exchangers comprise the termination of the second ends of said cavities. The latent heat generates steam in a pressurized vessel. This invention generates electricity, heating and cooling without moving parts.

### CROSS REFERENCES TO RELATED APPLICATIONS

Ser. No. 13/919,841 A Generator of Electricity Using Induced Vibrational and Acoustic Potential Energy Reclamation, 2013, Timothy J. Sipp

### REFERENCES CITED

NONE

### BACKGROUND OF THE INVENTION

1. Field of the Invention

This invention relates to the field of alternative energy generation and energy harvesting while coproducing heating and cooling. Specifically, this invention comprises a plurality of pressurized sequentially perpendicularly coupled and tuned piezoelectric resonators that mechanically amplifies ambient and induced Sound Pressure Levels via Standing Wave Resonance such that the anti-node of the Natural Resonant Frequency in each resonator occurs in a plane consistent with the coupling port of the subsequent resonator thereby acting as a mechanically amplified acoustic driver for the proceeding resonator until acoustically driving mechanically coupled and tuned Piezoelectric Helmholtz resonators with physical parameters such that Standing Wave Resonance occurs within the Piezoelectric Helmholtz Resonant Cavities and Acoustic Refrigeration Units comprising cylindrical resonant cavities with axial regenerating stacks acted upon by tuned frequencies such that the hot heat exchangers are in the center of said cavities while the cold heat exchangers comprise the termination of the second ends of said cavities. The latent heat generates steam in a pressurized vessel. This invention is self-sustaining after a period, extensible, scalable, encompassing microsystems printed and grown on wafers scaled up to macro-systems for industrial power production, and generates electricity, heating and cooling without moving parts. The Piezoelectric Resonant Cavities are comprised of Gallium Nitride on Silicon Carbide substrates with a Nano-Silver Matrix bonded to and contained within Titanium inner shells the externality of which are coated in Titanium Nitride with the purpose of translating acoustic and vibrational energy into consumable electricity. The latent heat byproduct is exchanged through submersion in liquid water contained in a vessel producing pressurized steam for driving mechanical-electrical generators. This process is energy efficient by recovering significant heat energy generated by friction and high pressures. This process provides a safety mechanism to prevent catastrophic systems failure due to overheating and subsequent material fatigue, provides cooling for condensing steam for cold water return, and cryogenic cooling for external systems. This system design reduces unwanted sound and vibration transmission to a wider environment.

2. Description of the Related Art

Most piezoelectric devices and configurations have been transducer arrays developed to register physical changes in pressure and temperature, and/or detect and/or emit electromagnetic radiation. These devices and configurations comprise sensor arrays for scientific research, industrial uses, and satellite communications and also as microphones for audio transmission and recording. Resonating cavities have known qualities of internal mechanical amplification of a natural resonant frequency during standing wave resonance of 32 dB. Helmholtz resonators are widely used in science and industry for a variety of applications, usually as acoustic attenuators. These separate devices, piezoelectric transducer arrays and standing wave resonators, have not been utilized together to realize electric power generation, heating and cooling. To date no individual or industry has paired these devices together with intent or a reasonable expectation of translating induced vibration, compression and acoustic waves into usable electric power as well as coproducing heating and cooling. Previous piezoelectric devices did not generate sufficient electric charges when external mechanical deformation was applied to make them appropriate for generating usable electric power. Advances in manufacturing, lowered costs and increased availability of piezoelectrics like Gallium Nitride have increased the potential to generate usable electric power from this piezoelectric substance when combined with a plurality of sequentially mechanically coupled and tuned resonating columns and sequentially mechanically coupled and tuned Helmholtz cavities and Acoustic Refrigeration Units comprising cylindrical resonant cavities with axial regenerating stacks acted upon by tuned frequencies such that the hot heat exchangers are in the center of said cavities while the cold heat exchangers comprise the termination of the second ends of said cavities. The latent heat generates steam in a pressurized vessel. The cold heat exchangers protrude from the pressurized vessel in order to be coupled to working fluid based cooling systems. This invention generates electricity, heating and cooling without moving parts. The latent heat generated by this closed acoustic system is significant and will be exchanged in a pressurized vessel through submersion in liquid water producing pressurized steam for driving mechanical-electrical generators.

### BRIEF SUMMARY OF THE PRESENT INVENTION

This generator of electricity, heating and cooling using induced vibrational and acoustic potential energy reclamation is self-sustaining after a period, extensible, scalable, encompassing microsystems printed and grown on wafers scaled up to macro-systems for industrial power production, is comprised of no moving parts and in some embodiments will lower ambient noise levels by design. This generator of electricity, heating and cooling using induced vibrational and acoustic potential energy reclamation will in some embodiments be purpose built to be permanently coupled physically with a multi-coil Super-Cooled Super-Conducting Magnetic Energy Storage System (SMES) and provide both cooling to maintain the SMES and electricity to charge the SMES. The present invention, a plurality of pressurized sequentially mechanically coupled and tuned resonators mechanically amplifies induced Sound Pressure Levels via Standing Wave Resonance such that the anti-node of the Natural Resonant Frequency in each resonator occurs in a plane consistent with the coupling port of the subsequent resonator thereby acting as a mechanically amplified acoustic driver for the proceeding resonator until acoustically driving mechanically coupled and tuned Piezoelectric Helmholtz resonators with physical parameters such that Standing Wave Resonance occurs within the Piezoelectric Helmholtz Resonant Cavities and Acoustic Refrigeration Units comprising cylindrical resonant cavities with axial regenerating stacks acted upon by tuned frequencies such that the hot heat exchangers are in the center of said cavities while the cold heat exchangers comprise the termination of the second ends of said cavities. The latent heat generates steam in a pressurized vessel. The cold heat exchangers protrude from the pressurized vessel in order to be coupled to working fluid based cooling systems. This invention generates electricity, heating and cooling without moving parts. The Piezoelectric transducer arrays are comprised of Gallium Nitride on Silicon Carbide substrates and a Nano-Silver Matrix bonded to and contained within Titanium inner shells externally coated in Titanium Nitride, are ring shaped for cylindrical resonators and take the shape and size of the mechanically coupled and tuned Piezoelectric Helmholtz resonating cavities. The latent heat produced by this closed system is exchanged in a pressurized vessel through submersion in liquid water producing pressurized steam for driving mechanical-electrical generators. This generator of electricity, heating and cooling using induced vibrational and acoustic potential energy reclamation will in some embodiments operate under pressures and temperatures sufficient to cause the pressurized noble gas to form a plasma state.

### BRIEF DESCRIPTION OF THE DRAWINGS

FIG. 1 is a top view diagram of the Piezoelectric Resonant Cavity System indicating mechanically coupled and tuned resonator types (1, 3, 5, 7) and Acoustic Refrigeration Units (9)

FIG. 2 is a front view diagram of the Piezoelectric Resonant Cavity System indicating mechanically coupled and tuned resonator types (1, 3, 5, & 7) and Acoustic Refrigeration Units (9)

FIG. 3 is a side view diagram of the Piezoelectric Resonant Cavity System indicating mechanically coupled and tuned resonator types (1, 3 & 7) and Acoustic Refrigeration Units (9)

FIG. 4 is a top view diagram of one of four branches of the Piezoelectric Resonant Cavity System indicating tuning plunger apparatus (11) of resonator types (1, 3 & 5) and Acoustic Refrigeration Unit (9)

FIG. 5 is a cross-section diagram, not to scale, of the Acoustic Refrigeration Units (ARUs) (9) utilizing an axial regenerating stack (63) such that the hot heat exchanger (61) is the middle of the ARU and the cold heat exchanger (65) is at the termination of the ARU.

FIG. 6 is a cross-section diagram, not to scale, of the material layers of the Piezoelectric Helmholtz Resonators (7) indicating the multiple layers of materials: (21) Titanium Nitride, (23) Titanium, (25) Silicon Carbide, (27) Nano-Silver Matrix, (29) Gallium Nitride.

FIG. 7 is a top view diagram of the mechanically coupled and tuned resonating columns with Piezoelectric Ring Arrays of types 31, 33, & 35. The exploded cross section diagram indicates the multiple layers of materials comprising the ring arrays: (21) Titanium Nitride, (23) Titanium, (25) Silicon Carbide, (27) Nano-Silver Matrix, (29) Gallium Nitride.

FIG. 8 is a side view diagram of the Mechanically Coupled and Tuned Piezoelectric Resonating Cavity System contained by a pressurized vessel (51) partially filled with water to the line (57) with a cold water return port (53) a water drainage plug (55) an interface for connecting cables or some other conveyance for consumable electricity (52) and a threaded/lipped steam-line connector port (59). The upper portion of the vessel separates at the seam (54) from the lower portion for installation, maintenance and access. The Cold Heat Exchanger (65) from an Acoustic Refrigeration Unit (9) protrudes from the pressurized vessel.

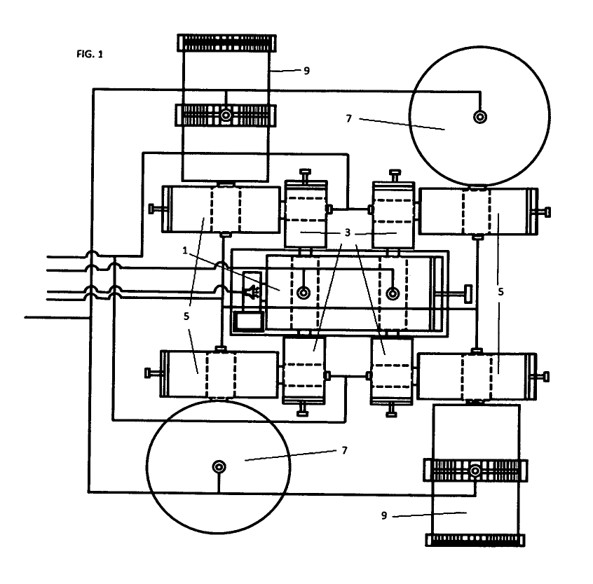

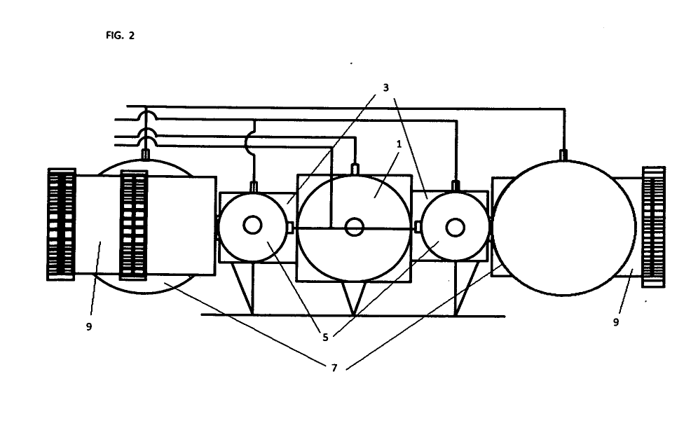

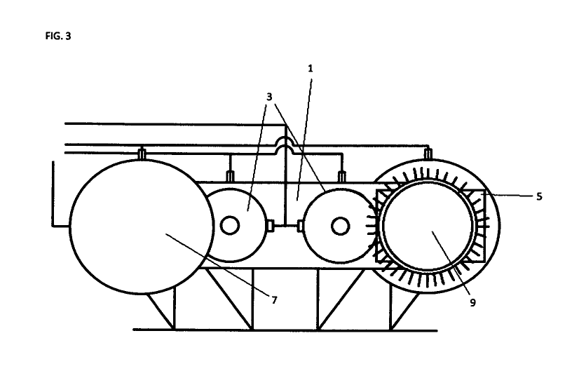

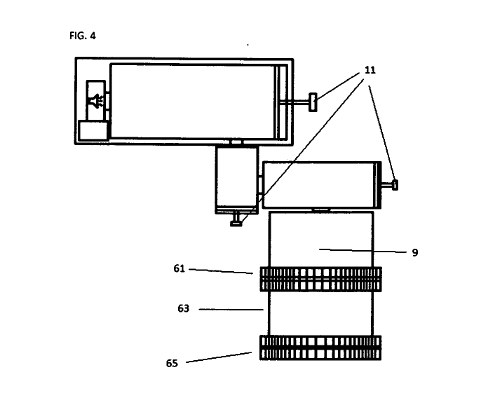

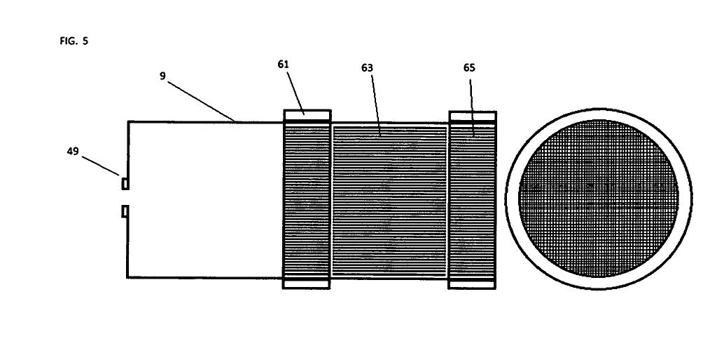

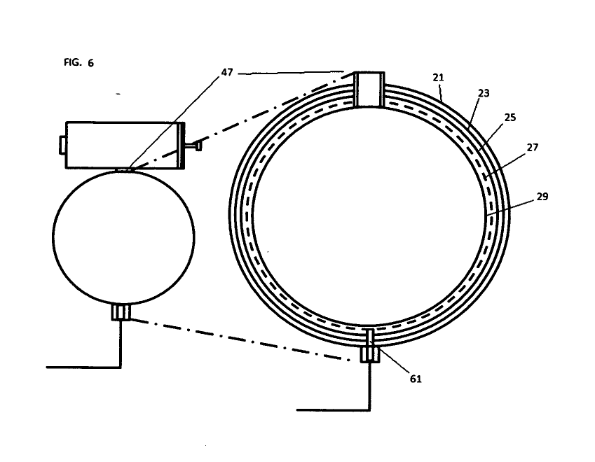

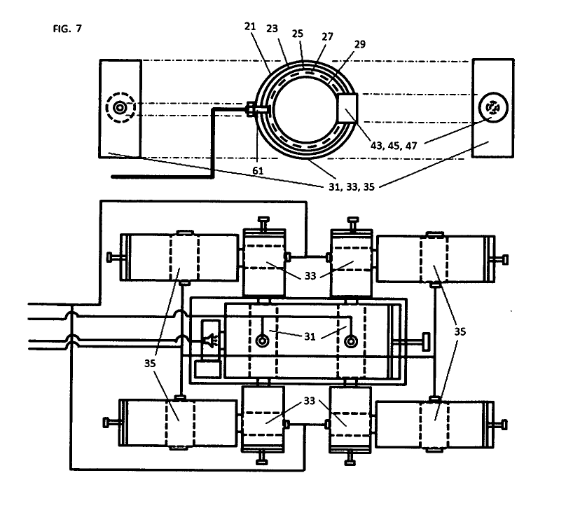

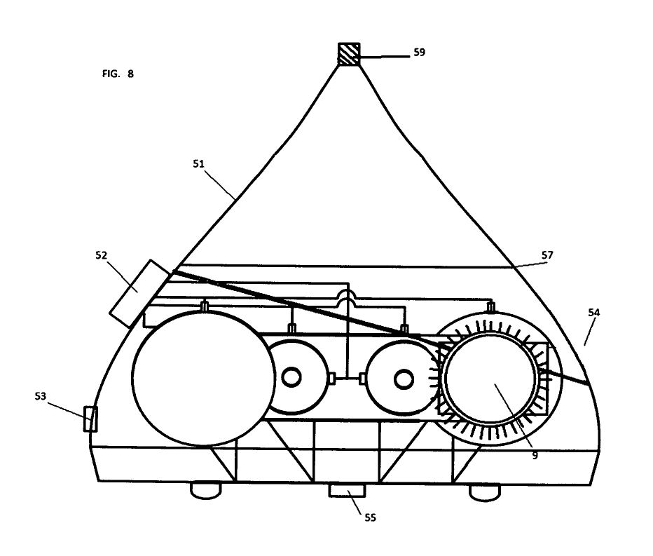

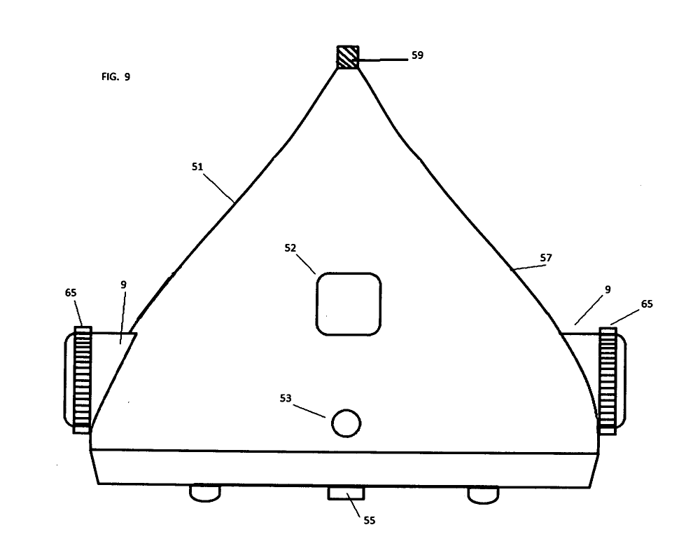

### DETAILED DESCRIPTION OF THE PRESENT INVENTION

A Generator of Electricity and Refrigeration Using Induced Vibrational and Acoustic Potential Energy Reclamation, comprising:
an acoustic driver (41) to induce sound waves, the induced sound can be the result of an electro-acoustic driver, a flow-induced oscillation as well as the result of some form of combustion;
a first piezoelectric resonator (1) connected to at a first end the acoustic driver (41), and at the other end to a plurality of mechanically coupled and tuned piezoelectric resonators (3, 5, 7);
   which plurality of mechanically coupled and tuned piezoelectric resonators mechanically connected together (43, 45, 47), with each piezoelectric resonator comprised of gallium nitride (29) on silicon carbide substrates (25) and a nano-silver matrix (27) bonded to and contained within titanium inner shells (23); with the externality of the titanium inner shells coated in titanium nitride (21);
   said mechanically coupled and tuned piezoelectric resonators being ring shaped (31, 33, 35) in cylindrical resonators (1, 3, 5) and sized to form Spheroidal Piezoelectric Helmholtz resonating cavities (7);
   each said mechanically coupled and tuned piezoelectric resonator is further connected to a tuning plunger (11) that can change the shape of that resonator's resonating cavity. Said plungers are capable of manual and automatic operations
each of which mechanically amplifies induced Sound Pressure Levels via Standing Wave Resonance such that the anti-node of the Natural Resonant Frequency in each resonator occurs in a plane consistent with each of the plurality of mechanically coupled and tuned piezoelectric resonators after the first further comprising a coupling port (43, 45, 47) of any of the subsequent resonators and Acoustic Refrigeration Units (9); The standing wave resonance in each resonator increases the SPL by 32 dB, there will be losses at the mechanical coupling (43, 45, 47) commensurate with spring losses, K, and frictional losses in the resonators necks, but the net increase in acoustic power is exponentially higher than the sum of the losses at each said mechanical coupling port; the net effect on acoustic power of this sequential mechanical amplification is positively exponential; for example, but in no way limiting this invention, a 10 watt 130 dB tuned acoustic wave passing through this plurality of sequentially mechanically coupled and tuned resonators could be mechanically amplified up to 200 dB equal to 100 MW of acoustic power; this is a closed acoustic system with no ducting which means heating of the air due to friction over time; the highest SPLs will be in the final mechanically coupled and tuned piezoelectric resonating columns and mechanically coupled and tuned piezoelectric Helmholtz resonators; These exponentially higher SPLs will also correspond to the highest thermal gains across the system; The heat generated from the piezoelectric resonant cavity system will be exchanged via submersion in liquid water in a closed vessel producing pressurized steam for driving mechanical-electrical generators; This process is efficient and provides a safety mechanism to prevent catastrophic failure due to overheating; This arrangement has the added benefit of reducing external sound transmission;
Acoustic Refrigeration Units (9) comprising cylindrical resonant cavities with axial regenerating stacks (63) acted upon by tuned frequencies such that the hot heat exchangers (61) are in the center of said cavities while the cold heat exchangers (65) comprise the termination of the second ends of said cavities The latent heat generates steam in a pressurized vessel (51), the cold heat exchangers (65) protrude from said pressurized vessel in order to be coupled to working fluid based cooling systems, this invention generates electricity, heating and cooling without moving parts;
means for isolating the generator from ground vibration; wherein the means for isolating the generator from ground vibration comprise triangular shaped legs;
an electrical storage facility capable of retaining an electrical charge (49) to initiate and operate the electro-acoustic driver (41) of the Piezoelectric Resonant Cavity System until the system is self-sustaining;
distributional means for conveying generated electrical charge (61) to be any of stored in some capacity, used directly by an electrically powered building, and transferred to any of a hybrid/electric vehicle and electronic device;
transformational means connected to each said mechanically coupled and tuned piezoelectric resonator to collect and turn into electrical energy the vibrational energy from each mechanically coupled and tuned piezoelectric resonator;
collection means connecting with each said transformational means connected to each said mechanically coupled and tuned piezoelectric resonator, and with the electrical storage facility, the acoustic driver, and the distributional means;

A Generator of Electricity and Refrigeration Using Induced Vibrational and Acoustic Potential Energy Reclamation, further comprising at least one system for monitoring operations, further comprising:
a set of sensor arrays distributed throughout the Piezoelectric Resonant Cavity System and pressurized steam vessel (51) externally connected through a port (52);

A Generator of Electricity and Refrigeration Using Induced Vibrational and Acoustic Potential Energy Reclamation, further comprising a closed vessel formed in an upwardly narrowing semi-conical taper producing pressurized steam (51) for driving mechanical-electrical generators containing liquid water, into which said first and plurality of mechanically coupled and tuned piezoelectric resonators are immersed to extract heat from the piezoelectric resonant cavity system while it is operating; and,

at least one mechanical-electrical driver connecting (59) to said closed vessel for using the pressurized steam generated thereby to transform the mechanical energy thereof into electrical energy;

Real world applications for the present invention include but are not limited to configurations in high-energy physics research facilities, cryogenics research facilities, public spaces such as, but not limited to, power generating stations, factories, stadiums, train stations & rail yards, subway stations, bus stations, airports, shipyards, ports, tunnels, bridges, highways, roadways, gymnasiums, concert halls, office buildings, hospitals, healthcare organizations, detention facilities, correctional facilities, military facilities, commercial spaces, retail spaces, and industrial & manufacturing spaces. Further applications could include, but not be limited to, handheld electronics and electrical equipment, vehicles and transportation of any configuration including but not limited to space-stations, spacecraft, sub-orbital craft, satellites, airplanes, helicopters, fixed-wing and rotary-wing aircraft, UAVs, MUAVs, parachutes, flying suits, flying armored suits, wearable computing platforms, diving suits, spacesuits, automobiles, trucks, construction vehicles, earthmovers, mining equipment, half-tracks, tracked vehicles, watercraft, hovercraft, submarines, motorcycles, unicycles, motor-scooters, ATVs, golf carts, and snowmobiles. The preceding examples constitute some, not all, possible configurations and applications of the present invention. Variations should not materially alter the nature of the present invention. Thus the scope of the invention should be fixed by the following claims rather than any specific example cited.

I claim:

1. A Generator of Electricity and Refrigeration Using Induced Vibrational and Acoustic Potential Energy Reclamation, comprising:
an acoustic driver;
a first piezoelectric resonator connected to at a first end the acoustic driver, and at the other end to a plurality of mechanically coupled and tuned piezoelectric resonators;
which plurality of mechanically coupled and tuned piezoelectric resonators mechanically connected together, with each piezoelectric resonator comprised of gallium nitride on silicon carbide substrates and a nano-silver matrix bonded to and contained within titanium inner shells; with the externality of the titanium inner shells coated in titanium nitride;
said mechanically coupled and tuned piezoelectric resonators being ring shaped in cylindrical resonators and sized to form Spheroidal Piezoelectric Helmholtz resonating cavities;
each said mechanically coupled and tuned piezoelectric resonator is further connected to a tuning plunger that can change the shape of that resonator's resonating cavity
As in claim 1, further comprising a manually-operated tuning plunger
As in claim 1, further comprising an automatically-operated tuning plunger
As in claim 1, further comprising a tuning plunger having both manual and automatic operating means
each of which mechanically amplifies induced Sound Pressure Levels via Standing Wave Resonance such that the anti-node of the Natural Resonant Frequency in each resonator occurs in a plane consistent with each of the plurality of mechanically coupled and tuned piezoelectric resonators after the first further comprising a coupling port of any of the subsequent resonators and Acoustic Refrigeration Units;
Acoustic Refrigeration Units comprising cylindrical resonant cavities with axial regenerating stacks acted upon by tuned frequencies such that the hot heat exchangers are in the center of said cavities while the cold heat exchangers comprise the termination of the second ends of said cavities; the latent heat generates steam in a pressurized vessel; the cold heat exchangers protrude from the pressurized vessel in order to be physically coupled to working fluid based cooling systems; this invention generates electricity, heating and cooling without moving parts
means for isolating the generator from ground vibration;
A generator as in claim 1, wherein the means for isolating the generator from ground vibration comprise triangular shaped legs
an electrical storage facility capable of retaining an electrical charge to initiate and operate the Piezoelectric Resonant Cavity System until the system is self-sustaining;
distributional means for conveying generated electrical charge to be any of stored in some capacity, used directly by an electrically powered building, and transferred to any of a hybrid/electric vehicle and electronic device;
transformational means connected to each said mechanically coupled and tuned piezoelectric resonator to collect and turn into electrical energy the vibrational energy from each mechanically coupled and tuned piezoelectric resonator;
collection means connecting with each said transformational means connected to each said mechanically coupled and tuned piezoelectric resonator, and with the electrical storage facility, the acoustic driver, and the distributional means.

2. A Generator of Electricity and Refrigeration Using Induced Vibrational and Acoustic Potential Energy Reclamation as in claim 1, further comprising at least one system for monitoring operations, further comprising:
a set of sensor arrays distributed throughout the Piezoelectric Resonant Cavity System and pressurized steam vessel externally connected through a port.

3. A Generator of Electricity and Refrigeration Using Induced Vibrational and Acoustic Potential Energy Reclamation as in claim 2, further comprising a closed vessel formed in an upwardly narrowing semi-conical taper producing pressurized steam for driving mechanical-electrical generators containing liquid water, into which said first and plurality of mechanically coupled and tuned piezoelectric resonators are immersed to extract heat from the piezoelectric resonant cavity system while it is operating; and,
at least one mechanical-electrical driver connecting to said closed vessel for using the pressurized steam generated thereby to transform the mechanical energy thereof into electrical energy.
